(19) United States
(12) Patent Application Publication
(10) Pub. No.: US 2003/0234415 A1
(43) Pub. Date: Dec. 25, 2003

(54) Scalable three-dimensional fringe capacitor with stacked via

(76) Inventor: Hwey-Ching Chien, San Diego, CA (US)

Correspondence Address: Hung Chang Lin, 8 Schindler Court, Silver Spring, MD, 20903, US

(21) Appl. No.: 10/176,830

(22) Filed: Jun. 24, 2002

(51) Int. Cl. H01L 27/108

(52) U.S. Cl. 257/303

(57) ABSTRACT

Integrated fringe capacitor is structured in an IC with multi-layer metal layers sandwiched between a top metal plate and bottom plate. The multi-layers are cut into vertically aligned islands and the islands are connect series through metallized vias to either the top metal plate or the bottom metal plate. The columns connected to the top metal plate and the columns connected to the bottom metal plate are placed close to each other form the capacitor.

### BACKGROUND OF THE INVENTION

(1) Field of the Invention

The invention relates to capacitors for integrated circuits

(2) Brief Description of Related Art

In an integrated circuit, it is desirable to integrate a capacitor as a circuit element to increase circuit density. The commonly used integrated capacitors are the PN junction capacitor, the metal-insulator-metal (MIM) capacitor (or poly-silicon/metal capacitor) as shown in FIG. 1A, and the fringe capacitor as shown in FIG. 1B. The capacitance of a PN junction capacitor is voltage dependent and generally has a low quality factor (Q) due to semiconductor resistance. The MIM capacitor as shown in FIG. 1A has a very thin dielectric 13 sandwiched between a top metal plate 12 and a bottom metal plate 11 and not available in many low-cost processing. The fringe capacitor, which depends on the vertical facing areas of two interdigital metals 21, 22 separated by a narrow gap 23, has very low capacitance per unit horizontal area, because metals are generally very thin.

### SUMMARY OF THE INVENTION

An object of this invention is to provide an integrated capacitor, which has high capacitance per unit area. Another object of this invention is to provide an integrated capacitor with voltage independent capacitance. Still another of this invention is to provide a low-cost integrated capacitor.

These objects are achieved by utilizing the fringe capacitance of via holes, which arc generally available in integrated circuits with multiple metal layers. The metal layer sandwiched between a top metal plate and bottom metal plates are cut into aligned islands connected in series by metallized through holes to either the top metal plate or the bottom metal plates. The two columns form the two electrodes of the capacitor.

### BRIEF DESCRIPTION OF THE SEVERAL VIEWS OF THE DRAWINGS

FIG. 1 shows prior art integrated capacitors, where FIG. 1A shows a metal-insulator-metal (MIM) capacitor, and FIG. 1B shows a fringe capacitor using top metal of multiple metals.

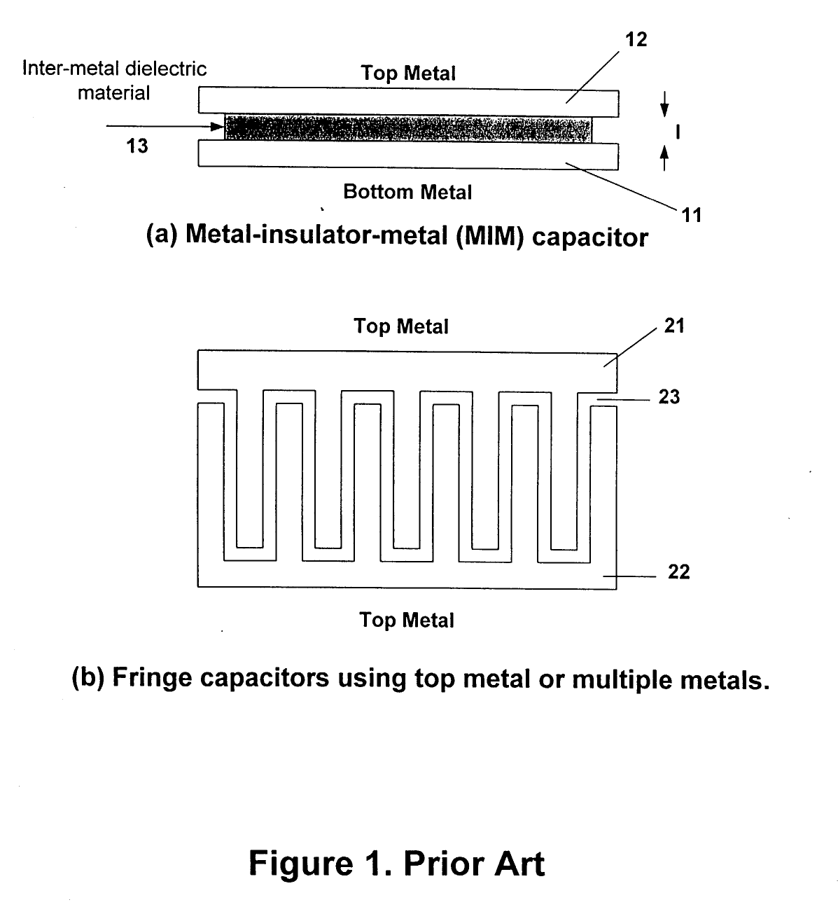

FIG. 2 shows the basic three dimension fringe capacitor of the present invention.

FIG. 3 shows the three-dimensional fringe capacitor with the use of “stacked via”.

FIG. 4 shows the top and bottom views of the three-dimension fringe capacitor.

FIG. 5 shows wall enclosure option of the present invention.

FIG. 6 shows polygon-shaped “stacked-via” capacitors.

FIG. 7 shows long rectangular vias to form the capacitors.

### DETAILED DESCRIPTION OF THE INVENTION

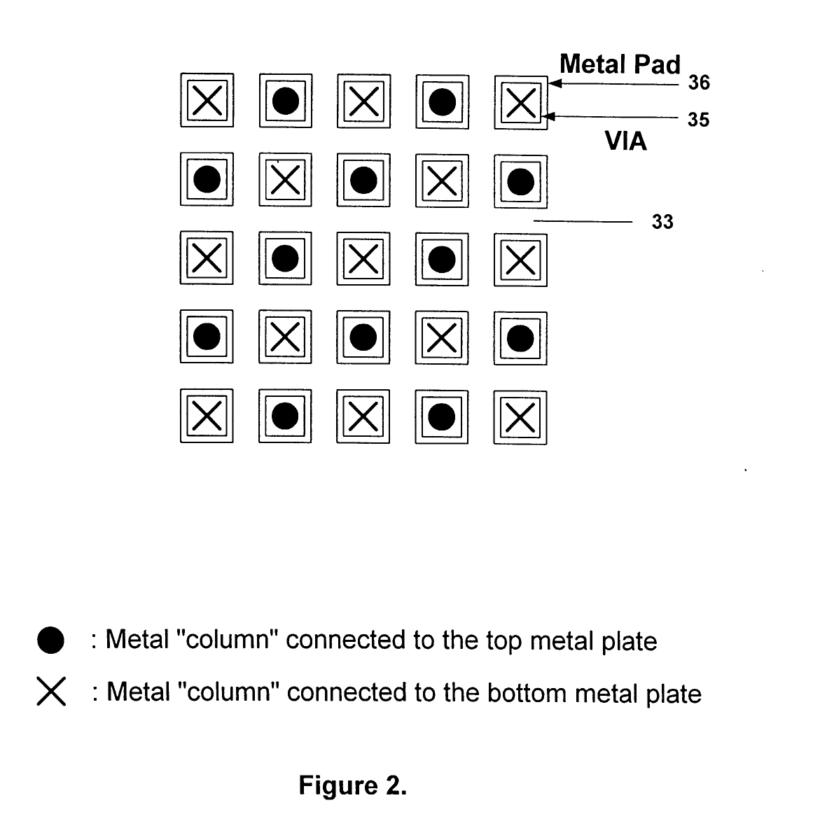

FIG. 2 shows the basic capacitor of the present invention. The invention is applicable to IC with multi-layer metallization, which most Ics incorporate today for more flexible interconnection and higher density. The interconnection between metal layers are provided with through-holes 35, commonly referred as “vias”, to make connection between layers, separated by one or more insulating layers. These insulating layer are relatively thick compared with metal layers. Hence, the walls of the vias have substantial vertical areas. These fringe areas are utilized to fabricate three-dimensional fringe capacitors in this invention.

FIG. 2 shows the top view of an array of the 3-D fringe capacitor. The inner square 35 at the top right corner is the via hole, and the outer square is metal pad 36 for contacting the via hole. The top right via forms a capacitor with the two adjacent vias. If the top right cross represents ac current flowing into the capacitor from a top metal plate, the dots in the two adjacent vias represent ac current flowing out from the capacitor into a bottom metal plate. The two kinds of vias are separated by a gap 33.

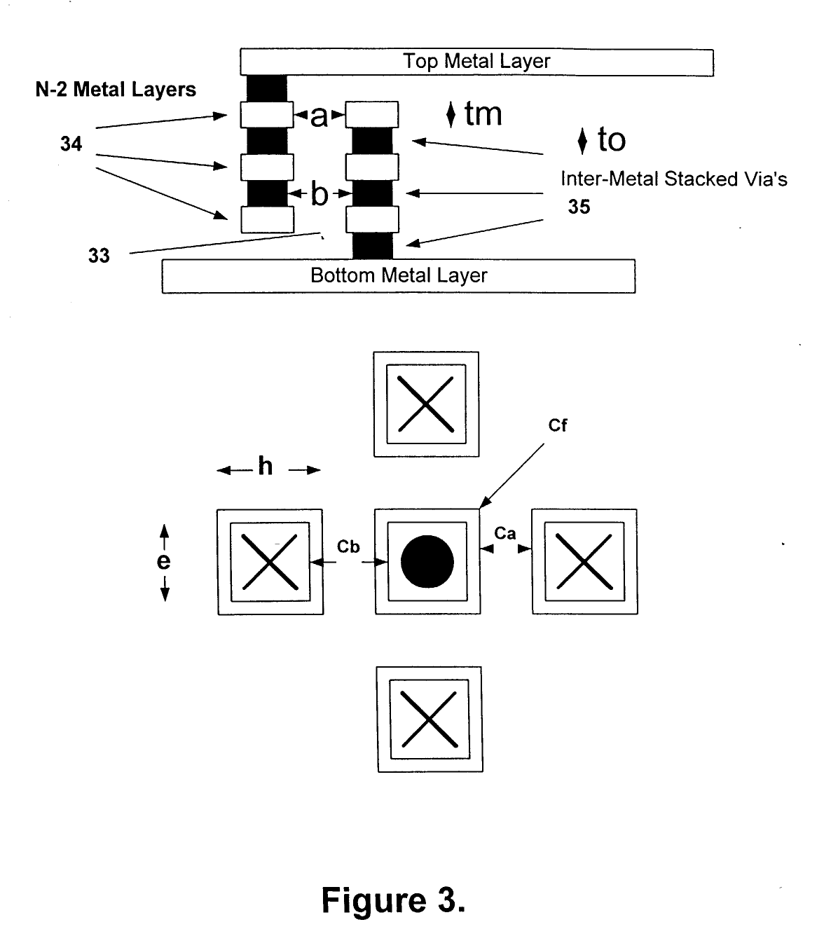

FIG. 3 shows a side view of the 3-D fringe capacitor. This particular structure has a top metal layer 31 and a bottom metal electrode 32 with three intermediate metal layers. At the left-hand side are three islands of three intermediate metal layers 34 hanging as a column under the top metal layer 31 through three vias. At the right-hand side, three islands of the three intermediate metal layers standing as a column over the bottom metal layer through three vias.35. The two vertical columns are placed close to each other to form the 3-D fringe capacitor. The layout of 3-D fringe capacitor must observe the layout rules of an IC. Dimension “a” is a minimum spacing between metals. Dimension “b” is the minimum width of metal pad. Dimension “h” is the minimum width of metal pad. Dimension “e” is the minimum width of via (metal pad must extend beyond the via boundary). Dimension “tm” is the metal thickness. Dimension “to” is the inter-metal dielectric thickness.

The capacitance between neighboring metal pad pair (with opposite polarity) for the 3-D fringe capacitor as shown in the top view of FIG. 3B can be derived as follows:

Ca=∈*(h*tm)/a (1)

The capacitance between via par (with opposite polarity) is given as follows:

Cb=∈*(e*to)/b, (2)

where ∈ is the dielectric constant of the inter-metal dielectric. The fringe capacitance per metal edge can be calculated with computer similation.

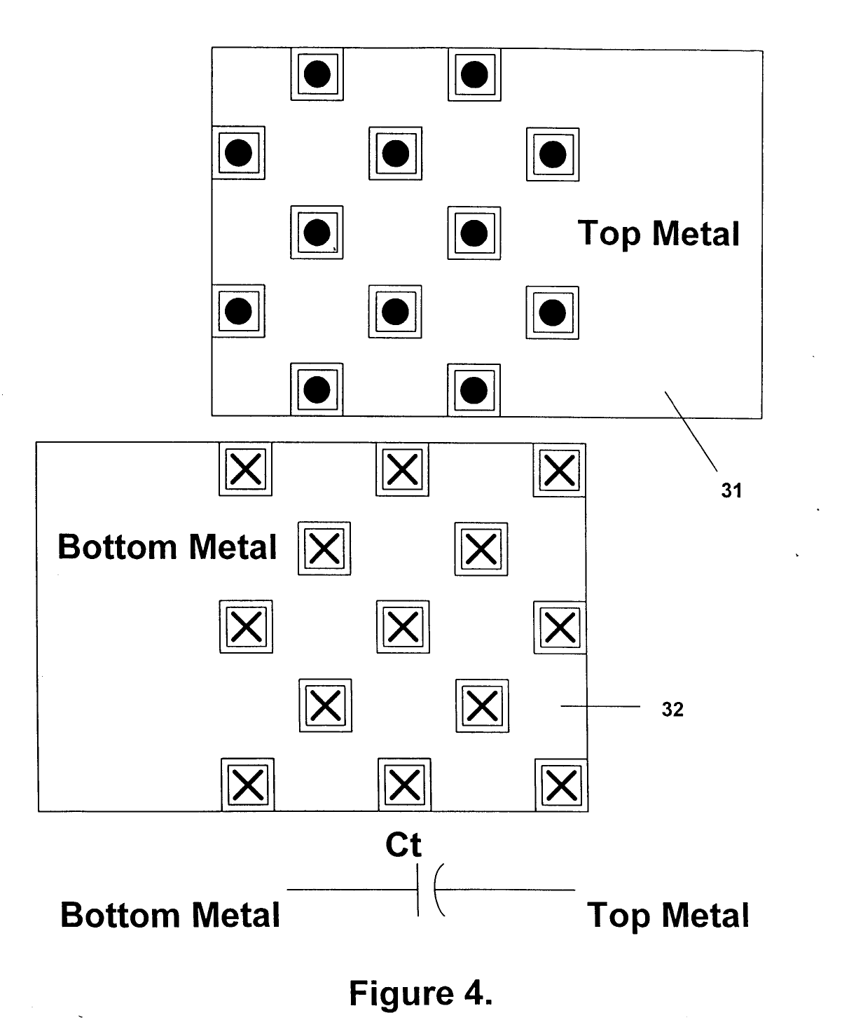

FIG. 4 shows the top and bottom views of top metal plate 31 and the bottom plate 32 respectively of the 3-D fringe capacitor. A large number of vias are connected in parallel to increase the capacitance. The crosses of the bottom metal 32 symbolize ac current flowing into the parallel vias of the fringe capacitor, and the dots in the to metal symbolize the ac current flowing out of the parallel vias of the fringe capacitor. For such a capacitor, the total capacitance per unit area Ct can be derived as follows:

Ct=((N−2)*4*Ca+(N−3)*4*Cb+(N−2)*4*Cf)*M (3)

where M is the upward metal column and downward metal column pairs per unit area, and N is the total number of metal layers.

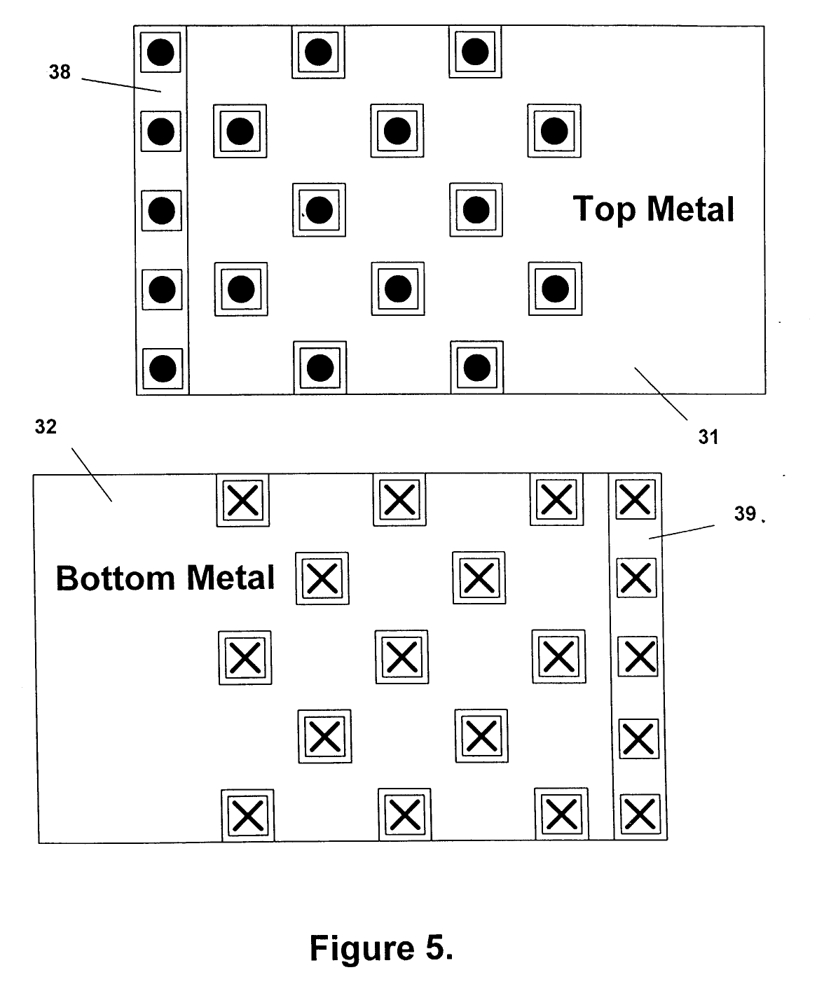

FIG. 5 shows a second embodiment of the present invention. [A through wall 39 is erected at the edge of the fringe capacitor as shown in right edge of the bottom metal] Through walls 38 and 39 are erected at the edges of the fringe capacitor, as shown in the left edge of the top metal and in the right edge of the bottom metal, to shield the electromagnetic field generated by ac current flowing in the vias. There are three options: no wall, wall connected to the top metal, and wall connected to the bottom metal (as shown). There are a total of 3*3*3*3*−81 possible wall enclosure configurations for the capacitor.

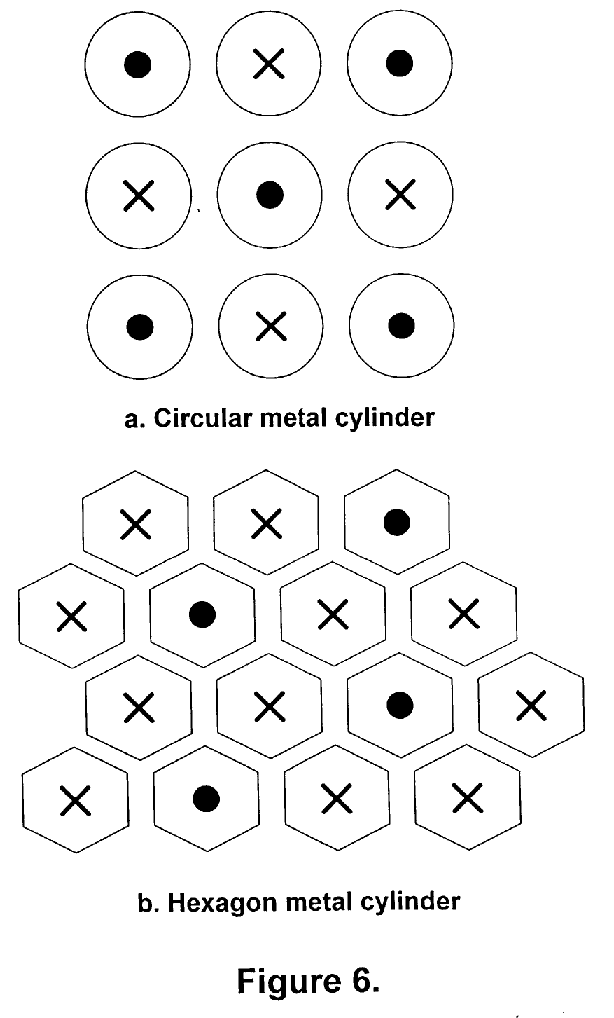

The shapes of metal pads and vias are not limited to squares shown in FIG. 2. FIG. 6 shows varieties of cylinder shapes of the pads and vias. In the upper figure (a) is shown circular metal cylinders 45. In the lower figure (b) is shown hexagon cylinders 55. The various polygon shapes are only constrained by semiconductor process and photolithography limitations. The capacitance per unit area varies with the choice of polygon shapes and arrangement.

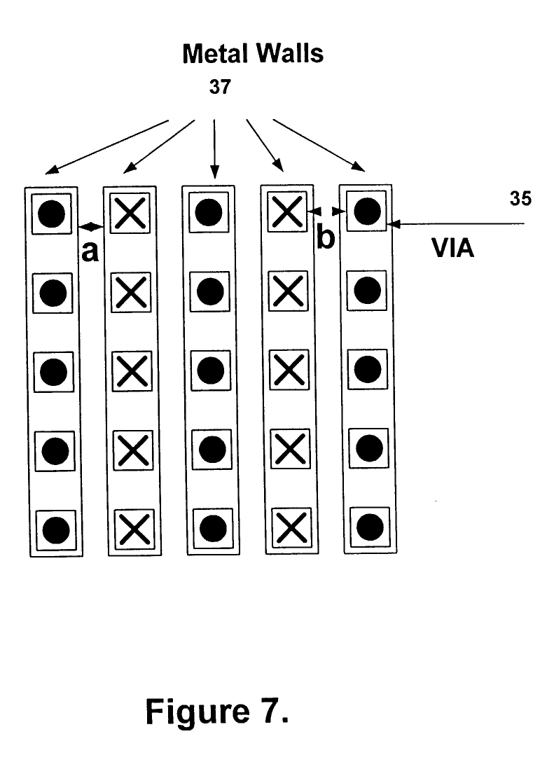

FIG. 7 shows another rectangular-shape via holes 37. This structure is a tradeoff between area capacitance and fringe capacitance.

The advantages of the present invention of 3-D fringe capacitor with “stacked VIA” are as follows:

1. the thickness of the inter-metal dielectric material dielectric material of the MIM capacitor does not scale with CMOS gate length. In the present invention, the minimum metal size, via size and metal spacing are all scaleable with CMOS gate length (or minimum geometry of other semiconductor processes if used). With the advancement of deep-sub-micron CMOS technology, the per-unit-area capacitance density of the present invention increases dramatically (inversely proportionate to the square of the minimum CMOS gate length).

2. The control of the inter-metal dielectric material of the MIM capacitor is much less precise then the control of metal dimension and spacing in all semiconductor technologies. A typical MIM capacitor has 20% of process variation. In the present invention, the capacitance is determined mainly by the lateral metal spacing which is precisely controlled especially in the deep-sub-micron CMOS technology (10% or less process variation can be achieved).

3. The use of the present invention can eliminate the use of MIM capacitor and thus reduce the cost of building the integrated circuit (the mask of the inter-metal-dielectric material is also eliminated).

4. The capacitor of the present invention has higher capacitance density than conventional fringe capacitor. With the used of the “stacked VIA”, the capacitance density also increases when the number of metal layers increases (as the trend of the CMOS technology).

While the preferred embodiments of the invention have been described, it will be apparent to those skilled in the art that various modifications can be made in the embodiments without departing from the spirit of the present invention. Such modifications are all within the scope of the present invention.

1. A capacitor for integrated circuit, comprising:
an integrated circuit;
a bottom metal plate deposited over said integrated circuit;
a top metal plate over said bottom metal layer;
at least one intermediate conducting layer interposed between said top metal plate and said bottom metal plate and patterned to yield at least two conducting islands;
insulating layers separating said at least intermediate conducting layer, said bottom metal plate and said top metal plate;
first kind of metallized via holes through one of said insulating layers each connecting said first island of said conducting islands to said bottom metal plate forming a first vertical column; and
second kind of metallized via holes through second insulating layer each connecting said second island of said conducting islands to said top metal plate forming a second vertical column, which forms a capacitor with said first vertical column.

2. The capacitor as described in claim 1, there are more than one said intermediate conducting layer, each having a first conducting island of said two conducting islands aligned with each other and connected in series by said first kind of metallized via holes, and having a second conducting island of said two conducting islands aligned with each other and connected in series by said second kind of metallized via holes.

3. The capacitor as described in claim 1, further comprising a long via hole wall enclosing said capacitor for shielding any electromagnetic field generated by current flowing in said sapacitor.

4. The capacitor as described in claim 1, further comprising pads for said first kind of metallized via holes and said second kind of via hole for bonding to said bottom metal plate and top metal plate respectively.

5. The capacitor as described in claim 1, wherein said via holes and said pads are squares.

6. The capacitor as described in claim 1, wherein said via holes and said pads are of cylindrical shape.

7. The capacitor as described in claim 1, wherein said via holes and pads are of hexagon shape.

8. The capacitor as described in claim 1, wherein said via holes are of elongated rectangular shape.
